(19) United States
(12) Patent Application Publication
(10) Pub. No.: US 2008/0048288 A1
(43) Pub. Date: Feb. 28, 2008

(54) SEMICONDUCTOR DEVICE

(76) Inventor: Jae-Won Han, Gyeongi-do (KR)

Correspondence Address: SHERR & NOURSE, PLLC, 620 HERNDON PARKWAY, SUITE 200, HERNDON, VA, 20170, US

(21) Appl. No.: 11/844,145

(22) Filed: Aug. 23, 2007

(30) Foreign Application Priority Data
Aug. 23, 2006 (KR) 10-2006-0080119

(51) Int. Cl. H01L 29/00; H01L 21/02

(52) U.S. Cl. 257/531; 438/381; 257/E29.001; 257/E21.022

(57) ABSTRACT

Embodiments relate to a semiconductor device and a fabrication method thereof. According to embodiments, the semiconductor device may includes a first substrate including an inductor cell, a second substrate including a RF (radio frequency) device circuit having a transistor and a wire, and a connection electrode for electrically connecting the inductor cell and the RF device circuit. The first and second substrates may be fabricated independently of each other.

The present application claims priority under 35 U.S.C. 119 and 35 U.S.C. 365 to Korean Patent Application No. 10-2006-0080119 (filed on Aug. 23, 2006), which is hereby incorporated by reference in its entirety.

### BACKGROUND

An inductor may operate as a coil in a circuit as one of the elements in the circuit for receiving and transmitting high frequency. An inductor may be fabricated as part of a semiconductor device. An inductor may be shaped as a spiral coil structure and may be formed using known semiconductor fabrication techniques.

An inductor has often been used in an RF device or an analog device. Such devices have become popularly used due to the expansion of a RF communication market.

### SUMMARY

Embodiments relate to a semiconductor device and a method for fabricating a semiconductor device.

Embodiments relate to a semiconductor device and a method of fabrication that may simplify a fabrication processes and may improve a fabrication yield.

According to embodiments, a semiconductor device may include a first substrate including an inductor cell, a second substrate including a RF (radio frequency) device circuit having a transistor and a wire, and a connection electrode for electrically connecting the inductor cell and the RF device circuit.

According to embodiments, a method for fabricating a semiconductor device may include forming a first substrate having an inductor cell, and a second substrate having a RF (radio frequency) device circuit with a transistor and a wire, and stacking the first substrate on the second substrate, and electrically connecting the inductor cell to the RF device circuit.

### DRAWINGS

FIG. 1 is a drawing illustrating a substrate having inductor cells formed by a method of fabricating a semiconductor device according to embodiments.

FIG. 2 is a cross-sectional view of a substrate having inductor cells formed by a method of fabricating a semiconductor device according to embodiments.

FIG. 3 is a diagram illustrating a substrate with a circuit unit formed by a method of fabricating a semiconductor device according to embodiments.

FIG. 4 is a diagram illustrating a semiconductor device having an inductor formed by a method of fabricating a semiconductor device according to embodiments.

### DETAILED DESCRIPTION

Embodiments relate to a method for effectively fabricating a semiconductor device having an inductor by separately fabricating a first substrate having an inductor cell and a second substrate having a RF device circuit unit, and then stacking the first second substrates. The inductor cell formed on the first substrate may be electrically connected to the RF device circuit unit formed on the second substrate through a connection electrode. According to embodiments, the inductor cell denotes an area where an inductor formed. In the inductor cell, a spiral metal pattern may be formed.

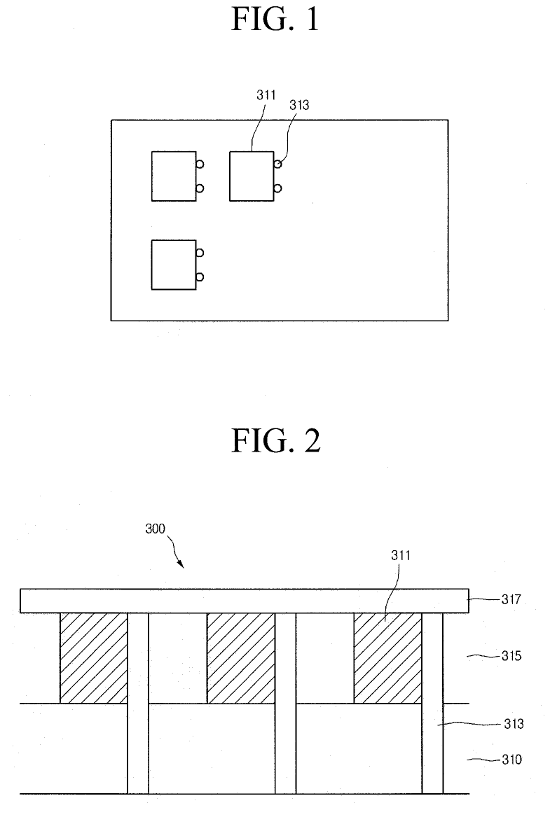

According to embodiments, first substrate 300 may include inductor cell 311 and penetration electrode 313, and may be fabricated as illustrated in FIG. 1 and FIG. 2.

According to embodiments, insulation layer 315 may be formed on semiconductor substrate 310, and a patterning process may be performed to form inductors. An etching process may then be performed, and a metal deposition process may be performed, which may form an inductor barrier. A filling process may be performed to form an inductor metal layer. Inductor cell 311 may be formed, for example, by performing a chemical mechanical planarization (CMP) process.

Electrode 313 may be formed and may penetrate semiconductor substrate 310 and may be connected to inductor cell 311. Electrode 313 may be formed through sequentially performing a pattern process, an etching process, a metal forming process, and a CMP process on semiconductor substrate 310. Since those processes are well-known to those skilled in the art a detailed description thereof will be omitted herein.

Inductor cell 311 and penetration electrode 313 may be made of at least one of materials including W, Cu, Al, Ag, and Au. Inductor cell 311 and penetration electrode 313 may be deposited through a chemical vapor deposition (CVD) process, a physical vapor deposition (PVD) process, an Evaporation process, or an electrochemical planting (ECP) process. In embodiments, a barrier metal of inductor cell 311 and penetration electrode 313 may be TaN, Ta, TiN, Ti, or TiSiN. In embodiments, the barrier metal may be formed through a CVD process, a PVD process, or an atomic layer deposition (ALD) process.

Passivation layer 317 may be formed on inductor cell 311.

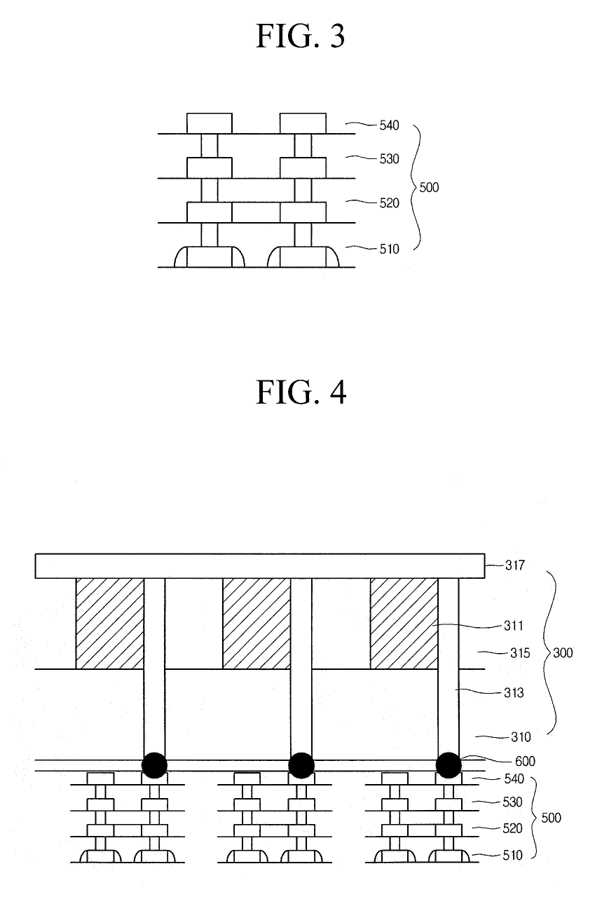

Referring to FIG. 3, second substrate 500 may include transistor layer 510, first metal layer 520, second metal layer 530, and third metal layer 540, and may be fabricated by a method for fabricating a semiconductor device according to embodiments. Other methods of forming second substrate including a transistor layer and metal layers could be used, as known in the art.

IN embodiments, transistor layer 510, and first, second, third metal layers 520, 530, and 540 may form a RF device circuit unit that may process signals. Although FIG. 3 shows three metal layers 520, 530, and 540 formed on the semiconductor layer, in embodiments the number of metal layers formed in second substrate 500 can vary according to the design thereof.

Referring to FIG. 4, first substrate 300 and second substrate 500 may be stacked together.

The semiconductor device with the inductor formed according to embodiments may include first substrate 300, second substrate 500, and connection electrode 600. Connection electrode 600 may connect inductor cell 311 formed on first substrate 300 to a RF device circuit formed on second substrate 500. The connection electrode 600 may be electrically connected to inductor cell 311 through penetration electrode 313 formed on first substrate 300. Connection electrode 600 may be connected to the top electrode forming third metal layer 540 that may form the RF device circuit.

The semiconductor device having the inductor formed using system in a package (SiP) as described above may have various advantages.

For example, according to embodiment, since a first substrate fabricating process for fabricating an inductor cell, and a second substrate fabricating process for forming a transistor and a metal wire may be independently performed, if an error occurs in the first substrate fabricating process, the second substrate having the transistor and the metal wire may not need to be wasted or discarded.

According to embodiments, since the penetration electrode may connect the inductor to the RF device circuit including the transistor with a significant separation distance, cross talk caused by the inductance may be reduced. Therefore, the characteristics of the RF semiconductor device having the inductor may be improved.

In embodiments, it may be possible to maximize the use of an inductor by separately fabricating a substrate having an inductor cell.

In embodiments, it may be possible to form a RF (radio frequency) device circuit not influenced by an inductor cell fabricating process because the inductor cell fabricating process can be performed separately from a transistor and metal wire forming process.

In embodiments, the semiconductor device and the fabrication method thereof may simplify a fabrication processes and improve a process yield.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device, comprising:
a first substrate comprising an inductor cell;
a second substrate comprising a radio frequency (RF) device circuit having a transistor and a wire; and
a connection electrode configured to electrically connect the inductor cell and the RF device circuit.

2. The device of claim 1, wherein the first substrate comprises:
the inductor cell formed over a semiconductor substrate; and
a penetration electrode connected to the inductor cell and penetrating the semiconductor substrate.

3. The device of claim 2, wherein the connection electrode is electrically connected to the inductor cell by the penetration electrode.

4. The device of claim 1, wherein the second substrate comprises:
a transistor layer having the transistor formed over a semiconductor substrate; and
a metal layer formed over the transistor layer.

5. The device of claim 2, wherein the inductor cell and the penetration electrode comprise at least one of one of W, Cu, Al, Au, and Au.

6. A method, comprising:
forming a first substrate comprising an inductor cell;
forming a second substrate comprising a radio frequency (RF) device circuit including a transistor and a wire; and
electrically connecting the inductor cell to the RF device circuit.

7. The method of claim 6, further comprising stacking the first substrate over the second substrate.

8. The method of claim 7, wherein forming the first substrate comprises:
forming the inductor cell over a semiconductor substrate; and
forming a penetration electrode connected to the inductor cell and penetrating the semiconductor substrate.

9. The method of claim 8, wherein the inductor cell and the RF device circuit are electrically connected through a connection electrode.

10. The method of claim 9, wherein the connection electrode is electrically connected to the inductor cell through the penetration electrode.

11. The method of claim 8, wherein the inductor cell and the penetration electrode comprise at least one of W, Cu, Al, Ag, and Au.

12. The method of claim 7, wherein forming the second substrate comprises:
forming a transistor layer having the transistor over a semiconductor substrate; and
forming a metal layer over the transistor layer.

13. The method of claim 7, wherein the first and second substrates are formed independently of each other.

14. The method of claim 7, wherein stacking the first and second substrates comprises providing a prescribed distance between the first and second substrates to reduce a cross-talk phenomenon caused by inductance.

15. A device, comprising:
an inductor cell formed over a semiconductor substrate in a first substrate;
a penetration electrode connected to the inductor cell and penetrating the semiconductor substrate in the first substrate;
a transistor layer having a transistor formed over a semiconductor substrate in a second substrate;
a metal layer formed over the transistor layer in the second substrate; and
a connection electrode configured to electrically connect the inductor cell and the transistor.

16. The device of claim 15, wherein the connection electrode is electrically connected to the inductor cell through the penetration electrode.

17. The device of claim 16, wherein the inductor cell and the penetration electrode comprise at least one of one of W, Cu, Al, Au, and Au.

18. The device of claim 15, wherein the first substrate and second substrate are physically distinct substrates coupled by the connection electrode.

19. The device of claim 15, wherein the first substrate is stacked over the second substrate.

20. The device of claim 19, wherein a distance between the first substrate and the second substrate is configured to reduce a cross-talk phenomenon caused by inductance.
